(19) United States
(12) Patent Application Publication
(10) Pub. No.: US 2026/0059766 A1
(43) Pub. Date: Feb. 26, 2026

(54) MEMORY DEVICE AND METHOD OF MANUFACTURING THE MEMORY DEVICE

(71) Applicant: Samsung Electronics Co., Ltd., Suwon-si (KR)

(72) Inventors: Soichiro MIZUSAKI, Suwon-si (KR); Kwangseok KIM, Suwon-si (KR); Jungsik PARK, Suwon-si (KR); Atsushi OKADA, Suwon-si (KR); Unghwan PI, Suwon-si (KR); Naoki HASE, Suwon-si (KR)

(73) Assignee: Samsung Electronics Co., Ltd., Suwon-si (KR)

(21) Appl. No.: 19/236,331

(22) Filed: Jun. 12, 2025

(30) Foreign Application Priority Data
Aug. 21, 2024 (KR) 10-2024-0112338

(51) Int. Cl. H10B 61/00; H10N 50/01; H10N 50/10; H10N 50/85

(52) U.S. Cl. CPC H10B 61/20; H10N 50/01; H10N 50/10; H10N 50/85

(57) ABSTRACT

A memory device according to at least one embodiment includes a heavy metal layer, a free layer on the heavy metal layer, a first dielectric layer on the free layer, the first dielectric layer including a first region and a plurality of second regions with the first region therebetween, a fixed layer in the first region of the first dielectric layer, and a second dielectric layer on the plurality of second regions of the first dielectric layer provided with the first region of the first dielectric layer therebetween, wherein the second dielectric layer may include an oxide including Mg, Al, Si, Hf, Ti, V, Cr, Mn, Fe, Co, Ni, Zn, or Zr, or any combination thereof.

### CROSS-REFERENCE TO RELATED APPLICATION

This application is based on and claims priority under 35 U.S.C. § 119 to Korean Patent Application No. 10-2024-0112338, filed on Aug. 21, 2024, in the Korean Intellectual Property Office, the disclosure of which is incorporated by reference herein in its entirety.

### BACKGROUND

### 1. Field

The disclosure relates to a memory device and a method of manufacturing the memory device.

### 2. Description of the Related Art

Racetrack memory devices use magnetic domains as memory units, and store information as 1 and 0 depending on the direction of the magnetic domain. Racetrack memory devices have a characteristic that a direction of moving the magnetic domains within the racetrack changes according to a direction in which current flows. Because the magnetic domains move relatively fast and the size of the magnetic domains is small, the magnetic domains draw attention as ultra-high-speed, high-capacity memory devices.

An ion beam etching process is used as a method of providing magnetic bonding devices in racetrack memory devices. However, when patterning is performed using the ion beam etching process, there is a problem that the deterioration of magnetic properties occurs in a metal ferromagnetic material of the racetrack memory device.

### SUMMARY

Provided are a memory device having a magnetic layer having perpendicular magnetic anisotropy and a method for manufacturing the memory device.

Additional aspects will be set forth in part in the description which follows and, in part, will be apparent from the description, or may be learned by practice of the presented embodiments of the disclosure.

According to an aspect of the disclosure, a memory device includes a heavy metal layer, a free layer on the heavy metal layer, a first dielectric layer on the free layer, the first dielectric layer including a first region and a plurality of second regions with the first region therebetween, a fixed layer on the first region of the first dielectric layer, and a second dielectric layer on the plurality of second regions of the first dielectric layer, the second dielectric layer including magnesium (Mg), aluminum (Al), silicon (Si), hafnium (Hf), titanium (Ti), vanadium (V), chromium (Cr), magnesium (Mn), iron (Fe), cobalt (Co), nickel (Ni), zinc (Zn), zirconium (Zr), or a combination thereof.

The second dielectric layer may include MgO, AlOx, SiOx, HfOx, or a combination thereof.

The first dielectric layer may include MgO.

The memory device may further include a third dielectric layer on the second dielectric layer.

The third dielectric layer may include at least one of SiO₂ or AlOx.

A thickness of the first region of the first dielectric layer in a vertical direction may be greater than a thickness of the second region of the first dielectric layer in the vertical direction.

The heavy metal layer may include at least one of iridium (Ir), ruthenium (Ru), tantalum (Ta), platinum (Pt), palladium (Pd), bismuth (Bi), titanium (Ti), and tungsten (W), or an alloy thereof.

The free layer may include cobalt (Co).

The free layer may have a synthetic anti-ferromagnetic (SAF) structure.

The SAF structure may include a first ferromagnetic layer, a non-magnetic layer, and a second ferromagnetic layer, which are sequentially stacked.

The first ferromagnetic layer may include a Co, Ni, and Co multilayer structure, the non-magnetic layer may include at least one of platinum (Pt), tungsten (W), tantalum (Ta), ruthenium (Ru), chromium (Cr), rhodium (Rh), palladium (Pd), molybdenum (Mo), niobdenum (Nb), or nickel (Ni), and the second ferromagnetic layer may include a CoFeB single layer.

The memory device may further include an electrode on the fixed layer.

The electrode may include at least one of TiN or Au.

According to another aspect of the disclosure, a memory device includes a heavy metal layer, a free layer provided on the heavy metal layer, a first dielectric layer on the free layer, the first dielectric layer including a plurality of first regions and a plurality of second regions with respective ones of the plurality of first regions therebetween, a plurality of fixed layers provided on the plurality of first regions of the first dielectric layer, and a second dielectric layer provided on the plurality of second regions of the first dielectric, the second dielectric layer including MgO, AlOx, SiOx, HfOx, or a combination thereof.

The first dielectric layer may include MgO.

The memory device may further include a third dielectric layer on the second dielectric layer.

The third dielectric layer may include at least one of SiO₂ or AlOx.

The memory device may further include an electrode on at least one of the plurality of fixed layers.

The memory device may further include a plurality of electrodes, each of the plurality of electrodes on a respective fixed layer of the plurality fixed layers.

The free layer may have a synthetic antiferromagnetic (SAF) structure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a memory device according to at least one embodiment;

FIG. 2 is a cross-sectional view showing a memory device according to at least one embodiment;

FIG. 3 is a cross-sectional view showing a memory device according to at least one embodiment;

FIG. 4 is a cross-sectional view showing a memory device according to at least one embodiment;

FIGS. 5A to 5C are schematic perspective views showing memory devices according to some embodiments.

FIGS. 6A to 6E are diagrams to explain a method of manufacturing a memory device, according to at least one embodiment; and

FIG. 7 is a conceptual diagram schematically showing a device architecture that may be applied to an electronic device according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. Additionally, repeat descriptions thereof may be omitted for brevity. As used herein, the term “and/or” includes any and all combinations of one or more of the associated listed items. Expressions such as “at least one of,” when preceding a list of elements, modify the entire list of elements and do not modify the individual elements of the list.

Hereinafter, memory devices and methods of manufacturing the memory devices according to various embodiments are described in detail with reference to the accompanying drawings, In the drawings below, like reference numerals refer to like components, and the size of each component in the drawings may be exaggerated for clarity and convenience of explanation. Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. The embodiments of the disclosure are capable of various modifications and may be embodied in many different forms.

When an element or layer is referred to as being “on” or “above” another element or layer, the element or layer may be directly on another element or layer or intervening elements or layers. The singular forms include the plural forms unless the context clearly indicates otherwise. When a part “comprises” or “includes” an element in the specification, unless otherwise defined, other elements are not excluded from the part and the part may further include other elements.

The term “above” and similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms as used herein are intended to include the plural forms as well unless the context clearly indicates otherwise. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the functional elements, including those including terms such as “unit,” “block,” “. . .controller,” etc. denote units that process at least one function or operation, and may be realized by and/or include processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Connections or connection members of lines between components shown in the drawings illustrate functional connections and/or physical or circuit connections, and the connections or connection members can be represented by replaceable or additional various functional connections, physical connections, or circuit connections in an actual apparatus.

All examples or example terms are simply used to explain in detail the technical scope of the disclosure, and thus, the scope of the disclosure is not limited by the examples or the example terms as long as it is not defined by the claims.

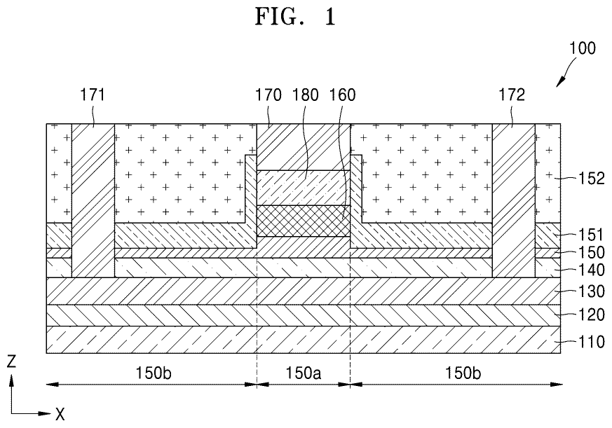

FIG. 1 is a cross-sectional view showing a memory device 100 according to at least one embodiment.

Referring to FIG. 1, the memory device 100 may include a heavy metal layer 130 on a substrate 110, a free layer 140 on the heavy metal layer 130, a first dielectric layer 150 on the free layer 140, a fixed layer 160 on a first region 150a of the first dielectric layer 150, and a second dielectric layer 151 on second regions 150b of the first dielectric layer 150. The memory device 100 may be, for example, a racetrack memory device.

The substrate 110 may include, for example, an elemental semiconductor (e.g., Si, Ge, SiGe, etc.) and/or a compound semiconductor (e.g., a Group III-V semiconductor material), but is not limited thereto. In at least some embodiments, a seed layer 120 may be further provided on the substrate 110.

The heavy metal layer 130 includes a non-magnetic heavy metal. The heavy metal layer 130 may include at least one of, for example, iridium (Ir), ruthenium (Ru), tantalum (Ta), platinum (Pt), palladium (Pd), bismuth (Bi), titanium (Ti), and tungsten (W), an alloy thereof, etc., but is not limited thereto.

The free layer 140 includes a ferromagnetic material. The free layer 140 may include, for example, cobalt (Co) and/or a cobalt (Co) alloy, but is not limited thereto. The free layer 140 may be configured such that a magnetic domain may be created within the free layer 140. The free layer 140 may include, for example, multiple layers.

The heavy metal layer 130, the free layer 140, and the first dielectric layer 150 may be collectively referred to as a racetrack line (RT-line). The magnetic domain may move through the RT-line.

The first dielectric layer 150 may include an oxide. The first dielectric layer 150 may include, for example, MgO. The first dielectric layer 150 may include the first region 150a and the second regions 150b provided with the first region 150a therebetween. The first region 150a may also be a central region of the first dielectric layer 150, and the second region 150b may be edge regions of the first dielectric layer 150. The second regions 150b may be damaged areas due to an ion beam etching process during the manufacturing process. A thickness of the first region 150a in a vertical direction (Z-axis direction) may be greater than a thickness of the second regions 150b in the vertical direction (Z-axis direction).

The fixed layer 160 may be on the first region 150a of the first dielectric layer 150. The fixed layer 160 may have a fixed magnetization direction. The fixed layer 160 may be configured such that the magnetization direction of the fixed layer 160 may not change in the operational conditions of the memory device 100 once the magnetization direction is determined. On the other hand, the free layer 140 may have a variable magnetization direction. Data may be read in response to the variable magnetization direction of the free layer 140.

The free layer 140, the first dielectric layer 150, and the fixed layer 160 may form a magnetic tunnel junction (MTJ) structure. At this time, the first dielectric layer 150 may act as a tunnel barrier for the MTJ. The free layer 140, the first dielectric layer 150, and the fixed layer 160 may be referred to as a tunneling magnetoresistance layer. Data may be read through the tunneling magnetoresistance layer.

A capping layer 180 may be on the fixed layer 160. The capping layer 180 is configured to prevent (or reduce) diffusion between the fixed layer 160 and a first electrode 170. The capping layer 180 may include, for example, ruthenium (Ru), tantalum (Ta), titanium (Ti), platinum (Pt), an alloy thereof, etc.

The second dielectric layer 151 may be in the second region 150b of the first dielectric layer 150. The second dielectric layer 151 may include an oxide. The second dielectric layer 151 may include an oxide including Mg, Al, Si, Hf, Ti, V, Cr, Mn, Fe, Co, Ni, Zn, or Zr, a combination thereof, etc. The second dielectric layer 151 may include, for example, magnesium oxide (MgO), aluminum oxide (AlOx), silicon oxide (SiOx), hafnium oxide (HfOx), or a combination thereof.

The second dielectric layer 151 may be on the second regions 150b of the first dielectric layer 150. The second dielectric layer 151 may surround the first dielectric layer 150, the fixed layer 160, and the capping layer 180 on the first region 150a of the first dielectric layer 150. For example, the second dielectric layer 151 may surround sidewalls of the fixed layer 160 and the capping layer 180. The second dielectric layer 151 may also be on at least a portion of sidewalls of the first electrode 170. The second dielectric layer 151 may include a horizontal portion and a vertical portion extending vertically to surround the first dielectric layer 150, the fixed layer 160, and the capping layer 180 on the first region 150a. A vertical thickness (Z-axis direction) of the horizontal portion of the second dielectric layer 151 may be, for example, 1 nm or more. The vertical thickness (Z-axis direction) of the horizontal portion of the second dielectric layer 151 may be, for example, 5 nm or more.

During a manufacturing process of the memory device 100, a thickness of the second region 150b of the first dielectric layer 150 may be reduced by ion beam etching, and thus, the perpendicular magnetic anisotropy (PMA) of the free layer 140 may disappear. However, the second dielectric layer 151 in the second region 150b of the first dielectric layer 150 is configured to restore the PMA of the free layer 140.

A third dielectric layer 152 may be on the second dielectric layer 151. The third dielectric layer 152 may include an oxide or a nitride. The third dielectric layer 152 may include, for example, SiO₂, AlOx, and/or the like.

The first electrode 170 may be on the capping layer 180. The first electrode 170 may include a conductor (e.g. a zero-band gap material), for example, TiN or Au. A second electrode 171 and a third electrode 172 may be on the heavy metal layer 130. The second electrode 171 and the third electrode 172 may penetrate the free layer 140, the first dielectric layer 150, the second dielectric layer 151, and the third dielectric layer 152. The second electrode 171 may include a conductor (e.g. a zero-band gap material), for example, TiN or Au. The third electrode 172 may include a conductor (e.g. a zero-band gap material), for example, TiN or Au.

In the memory device 100 according to at least one embodiment, the PMA of the free layer 140 may be restored as the second dielectric layer 151 is on the first dielectric layer 150.

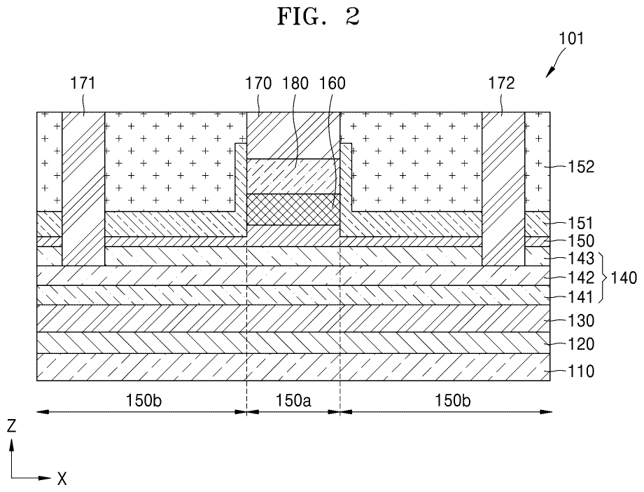

FIG. 2 is a cross-sectional view showing a memory device according to at least one embodiment.

Referring to FIG. 2, the memory device 101 may include a heavy metal layer 130 on a substrate 110, a free layer 140 on the heavy metal layer 130, a first dielectric layer 150 on the free layer 140, a fixed layer 160 on a first region 150a of the first dielectric layer 150, and a second dielectric layer 151 on a second region 150b of the first dielectric layer 150. The memory device 101 may be, for example, a racetrack memory device.

The free layer 140 may have a synthetic anti-ferromagnetic (SAF) structure. The free layer 140 may include a plurality of layers. The free layer 140 may include a first ferromagnetic layer 141, a non-magnetic layer 142, and a second ferromagnetic layer 143 that are sequentially stacked. A magnetization direction of the first ferromagnetic layer 141 may be opposite to a magnetization direction of the second ferromagnetic layer 143.

The first ferromagnetic layer 141 may include cobalt (Co), iron (Fe), boron (B), tungsten (W), ruthenium (Ru), iridium (Ir), platinum (Pt), molybdenum (Mo), or a combination thereof. The first ferromagnetic layer 141 may include, for example, a sequentially stacked Co, Ni, and Co multilayer structure, a Co, Pt, and Co multilayer structure, and/or a Co, Ir, and Co multilayer structure. The non-magnetic layer 142 may include a metal or an antiferromagnetic material. The non-magnetic layer 142 may include, for example, platinum (Pt), tungsten (W), tantalum (Ta), ruthenium (Ru), chromium (Cr), rhodium (Rh), palladium (Pd), molybdenum (Mo), niobium (Nb), nickel (Ni), or a combination thereof. The second ferromagnetic layer 143 may include, for example, a CoFeB single layer. The second ferromagnetic layer 143 may include, for example, sequentially stacked first to third layers, wherein the first layer may include Co or CoFe, the second layer may include W or Ta, and the third layer may include CoFeB or FeB.

The first dielectric layer 150 including MgO is on the second ferromagnetic layer 143, whereby the second ferromagnetic layer 143 has PMA characteristics.

The memory device 101 according to the example embodiments may be the same as (or substantially similar to) the memory device 100 of FIG. 1, except that the free layer 140 has a synthetic anti-ferromagnetic structure. In describing the memory device 101 of FIG. 2, descriptions previously given with reference to FIG. 1 are omitted.

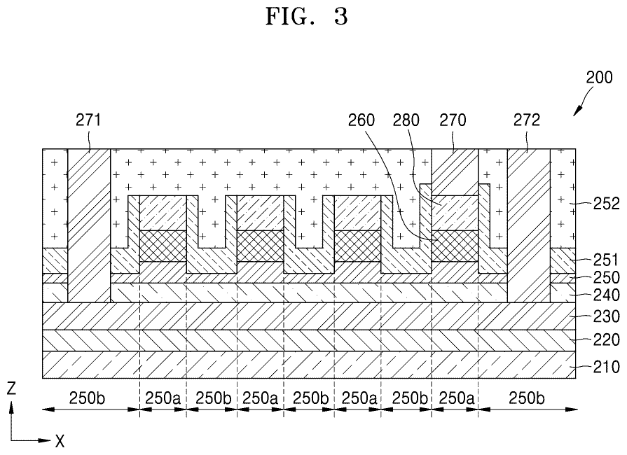

FIG. 3 is a cross-sectional view showing a memory device 200 according to at least one embodiment.

Referring to FIG. 3, the memory device 200 may include a heavy metal layer 230 on a substrate 210, a free layer 240 on the heavy metal layer 230, a first dielectric layer 250 on the free layer 240, a plurality of fixed layers 260 on a first region 250a of the first dielectric layer 250, and a second dielectric layer 251 on a second region 250b of the first dielectric layer 250. The memory device 200 may be, for example, a racetrack memory device.

A first electrode 270 may be on at least one of the plurality of fixed layers 260. Each of the plurality of fixed layers 260 may function as one cell. The memory device 200 may drive a plurality of cells by including the plurality of fixed layers 260. A capping layer 280 may be on each of the plurality of fixed layers 260.

The memory device 200 according to the embodiment may be the same as (or substantially similar to) the memory device 100 of FIG. 1 except that the memory device 200 includes a plurality of fixed layers 260. In describing the memory device 200 of FIG. 3, descriptions previously given with reference to FIG. 1 are omitted.

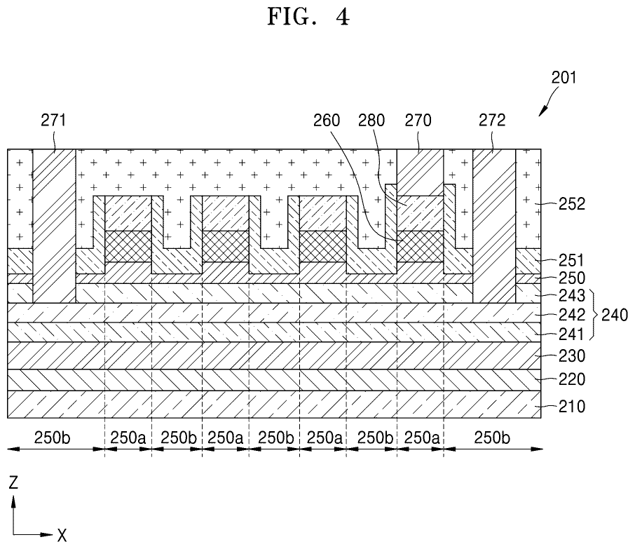

FIG. 4 is a cross-sectional view showing a memory device 201 according to at least one embodiment.

Referring to FIG. 4, the memory device 201 may include a heavy metal layer 230 on a substrate 210, a free layer 240 on the heavy metal layer 230, a first dielectric layer 250 on the free layer 240, a plurality of fixed layers 260 on a first region 250a of the first dielectric layer 250, and a second dielectric layer 251 on a second region 250b of the first dielectric layer 250. The memory device 201 may be, for example, a racetrack memory device.

The free layer 240 may have an SAF structure. The free layer 240 may include a plurality of layers. The free layer 240 may include a first ferromagnetic layer 241, a non-magnetic layer 242, and a second ferromagnetic layer 243 that are sequentially stacked. A magnetization direction of the first ferromagnetic layer 241 may be opposite to a magnetization direction of the second ferromagnetic layer 243.

The first ferromagnetic layer 241 may include cobalt (Co), iron (Fe), boron (B), tungsten (W), ruthenium (Ru), iridium (Ir), platinum (Pt), molybdenum (Mo), and/or a combination thereof. The first ferromagnetic layer 241 may include, for example, a Co, Ni, and Co multilayer structure, a Co, Pt, and Co multilayer structure, or a Co, Ir, and Co multilayer structure that are sequentially stacked, respectively. The non-magnetic layer 242 may include, for example, platinum (Pt), tungsten (W), tantalum (Ta), ruthenium (Ru), chromium (Cr), rhodium (Rh), palladium (Pd), molybdenum (Mo), niobdenum (Nb), nickel (Ni), and/or a combination thereof. The second ferromagnetic layer 243 may include, for example, a CoFeB single layer. The second ferromagnetic layer 243 may include, for example, first to third layers that are sequentially stacked, wherein the first layer includes Co or CoFe, the second layer includes W or Ta, and the third layer includes CoFeB or FeB.

The memory device 201 according to the embodiment may be the same as (or substantially similar to) the memory device 200 of FIG. 3, except that the free layer 240 has a synthetic anti-ferromagnetic structure. In describing the memory device 201 of FIG. 4, descriptions previously given with reference to FIG. 1, FIG. 2, and FIG. 3 are omitted.

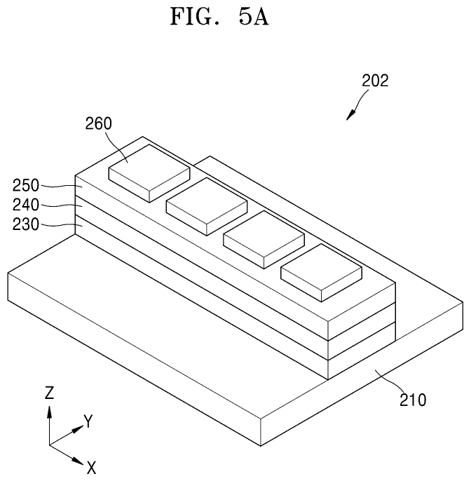

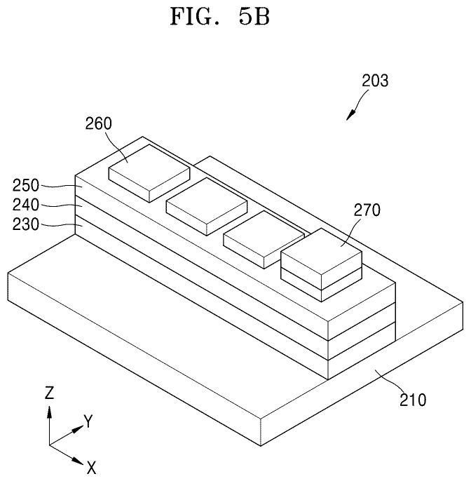

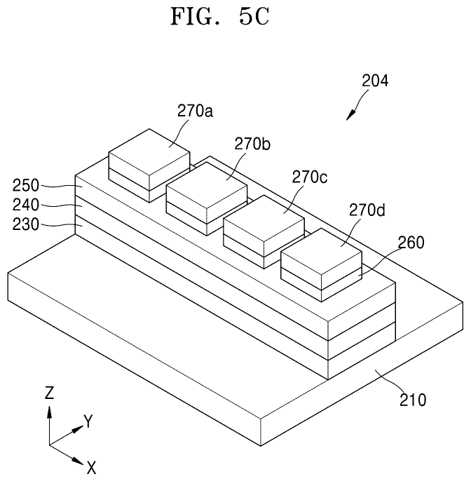

FIGS. 5A to 5C are schematic perspective views illustrating memory devices according to some embodiments.

Referring to FIG. 5A, a memory device 202 may include a heavy metal layer 230 on a substrate 210, a free layer 240 on the heavy metal layer 230, a first dielectric layer 250 on the free layer 240, and a plurality of fixed layers 260 on the first dielectric layer 250. Each of the plurality of fixed layers 260 may act as one cell. The memory device 202 may drive a plurality of cells by including a plurality of fixed layers 260.

Because electrodes are not on the plurality of fixed layers 260, the memory device 202 may be configured to not perform a data write operation but to perform a data transfer operation.

The plurality of fixed layers 260 are inside the first dielectric layer 250, that is, a thickness of the fixed layer 260 in a Y-axis direction is illustrated as less than a thickness of the first dielectric layer 250 in the Y-axis direction, but is not limited thereto. In another embodiment, the thickness of the fixed layer 260 in the Y-axis direction may be the same as (or substantially similar to) the thickness of the first dielectric layer 250 in the Y-axis direction.

Referring to FIG. 5B, a memory device 203 may include a heavy metal layer 230 on a substrate 210, a free layer 240 on the heavy metal layer 230, a first dielectric layer 250 on the free layer 240, a plurality of fixed layers 260 on the first dielectric layer 250, and an electrode 270 on one of the fixed layers 260.

Because the electrode 270 is on the plurality of fixed layers 260, the memory device 203 may be configured to perform both a data write operation and a data transfer operation.

Referring to FIG. 5C, a memory device 204 may include a heavy metal layer 230 on a substrate 210, a free layer 240 on the heavy metal layer 230, a first dielectric layer 250 on the free layer 240, a plurality of fixed layers 260 on the first dielectric layer 250, and a plurality of electrodes 270a, 270b, 270c, and 270d on each of the plurality of fixed layers 260.

Because the plurality of electrodes 270a, 270b, 270c, and 270d are on the plurality of fixed layers 260, the memory device 204 may configured to perform both a data write operation and a data transfer operation.

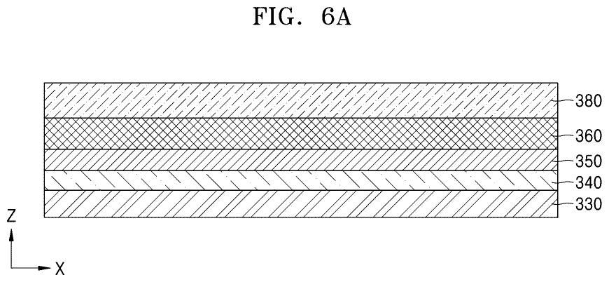

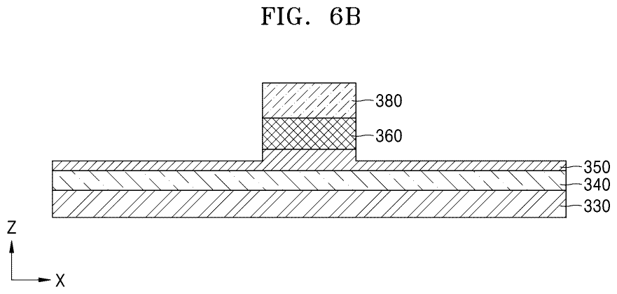

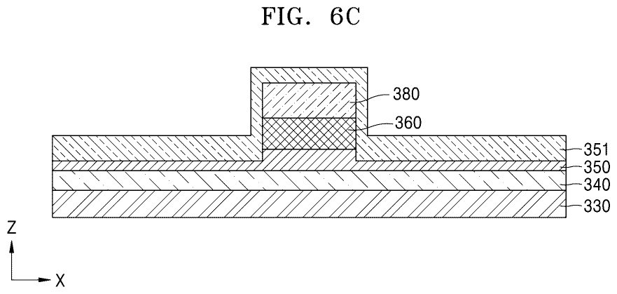

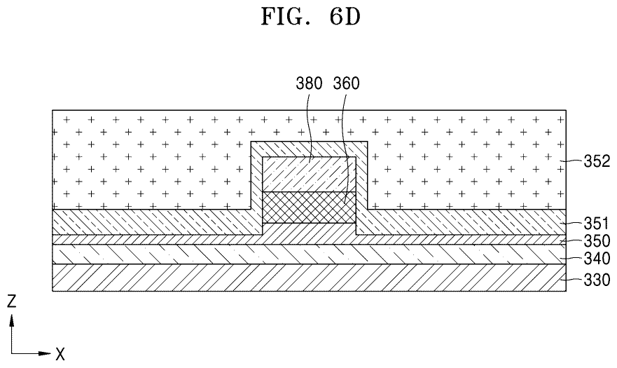

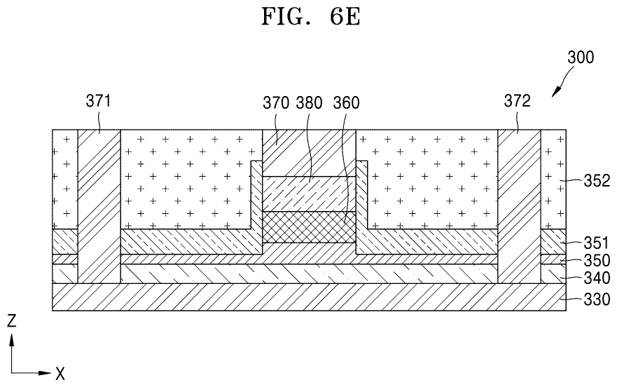

FIGS. 6A to 6E are diagrams to explain a method of manufacturing a memory device, according to at least one embodiment.

The heavy metal layer 330, free layer 340, first dielectric layer 350, second dielectric layer 351, third dielectric layer 352, fixed layer 360, first electrode 370, second electrode 371, and third electrode 372 of FIGS. 6A to 6E may be the same as (or substantially similar to) the heavy metal layer 130, the free layer 140, the first dielectric layer 150, the second dielectric layer 151, the third dielectric layer 152, the fixed layer 160, the first electrode 170, the second electrode 171, and the third electrode 172 of FIG. 1. Therefore, in describing FIGS. 6A to 6E, descriptions previously given with reference to FIG. 1 are omitted for brevity.

Referring to FIG. 6A, the free layer 340, the first dielectric layer 350, the fixed layer 360, and a capping layer 380 are sequentially on a heavy metal layer 330. The capping layer 380 may prevent (or reduce) diffusion between the fixed layer 360 and the first electrode 370 (see FIG. 6E). The capping layer 380 may include, for example, Ru, Ta, Ti, Pt, and/or a combination thereof.

Referring to FIG. 6B, a portion of each of the first dielectric layer 350, the fixed layer 360, and the capping layer 380 is etched through an ion beam etching process. In this process, a first region 350a of the first dielectric layer 350 is not etched, and second regions 350b of the first dielectric layer 350 are partially etched, and thus, a step difference may occur at a boundary between the first region 350a and the second regions 350b of the first dielectric layer 350. The second region 350b of the first dielectric layer 350 is partially etched, and thus, crystal characteristics of the first dielectric layer 350 may be changed.

Referring to FIG. 6C, the second dielectric layer 351 is provided on the first dielectric layer 350. The second dielectric layer 351 may surround the fixed layer 360 and the capping layer 380. As the second dielectric layer 351 is on the etched first dielectric layer 350, the PMA of the free layer 340 may be restored.

Referring to FIG. 6D, the third dielectric layer 352 is provided on the second dielectric layer 351. The third dielectric layer 352 may entirely cover the second dielectric layer 351.

Referring to FIG. 6E, a part of the second dielectric layer 351 on the capping layer 380 may be etched, a first electrode 370 may be provided on the capping layer 380, and a second electrode 371 and a third electrode 372 may be provided on the heavy metal layer 330 to be spaced apart from each other, thereby manufacturing a memory element 300. The second electrode 371 and the third electrode 372 respectively may be provided to penetrate the free layer 340, the first dielectric layer 350, the second dielectric layer 351, and the third dielectric layer 352.

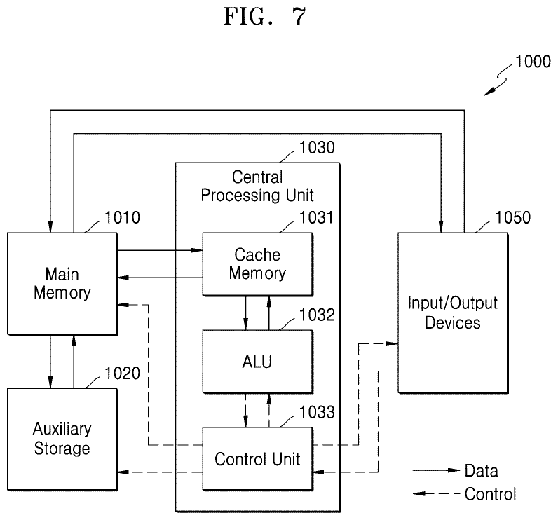

FIG. 7 is a conceptual diagram schematically showing a device architecture that may be applied to an electronic device 1000 according to embodiments.

Referring to FIG. 7, the electronic device 1000 may include a main memory 1010, an auxiliary storage 1020, a central processing unit (CPU) 1030, and an input/output device 1040. The CPU 1030 may include a cache memory 1031, an arithmetic logic unit (ALU) 1032, and a control unit 1033. The cache memory 1031 may include static random access memory (SRAM). The main memory 1010 may include, e.g., a dynamic random access memory (DRAM) device, and the auxiliary storage 1020 may include a memory device 100, 101, 200, or 201 according to at least one embodiment. Alternatively, the cache memory 1031, the main memory 1010, and the auxiliary storage 1020 may all include a memory device 100, 101, 200, or 201 according to at least one embodiment. In some cases, the electronic device 1000 may be implemented in a form in which computing unit devices and memory unit devices are adjacent to each other in one chip, without distinction of the sub-units described above.

According to the disclosure, a memory device in which the PMA of the free layer is restored and a method of manufacturing the memory device are provided by forming a second dielectric layer on the first dielectric layer.

According to the memory device and the method of manufacturing the memory device of the disclosure, the PMA of the free layer may be restored as the second dielectric layer is provided on the first dielectric layer. While the memory device and the method of manufacturing the memory device have been described with reference to the embodiments shown in the drawings, it will be understood by those of ordinary skill in the art that various changes in form and details may be made therein without departing from the spirit and scope of the disclosure. Therefore, the embodiments should be considered in a descriptive sense only and not for purposes of limitation. The scope of the disclosure is defined not by the detailed description of the disclosure but by the appended claims, and all differences within the scope will be construed as being included in the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a heavy metal layer;
a free layer on the heavy metal layer;
a first dielectric layer on the free layer, the first dielectric layer including a first region and a plurality of second regions with the first region therebetween;
a fixed layer on the first region of the first dielectric layer; and
a second dielectric layer on the plurality of second regions of the first dielectric layer the second dielectric layer including an oxide including magnesium (Mg), aluminum (Al), silicon (Si), hafnium (Hf), titanium (Ti), vanadium (V), chromium (Cr), magnesium (Mn), iron (Fe), cobalt (Co), nickel (Ni), zinc (Zn), zirconium (Zr), or a combination thereof.

2. The memory device of claim 1, wherein the second dielectric layer includes MgO, AlOx, SiOx, HfOx or a combination thereof.

3. The memory device of claim 1, wherein the first dielectric layer includes MgO.

4. The memory device of claim 1, further comprising:
a third dielectric layer on the second dielectric layer.

5. The memory device of claim 4, wherein the third dielectric layer includes at least one of SiO₂ or AlOx.

6. The memory device of claim 1, wherein a thickness of the first region of the first dielectric layer in a vertical direction is greater than a thickness of one of the plurality of second regions of the first dielectric layer in the vertical direction.

7. The memory device of claim 1, wherein the heavy metal layer includes at least one of iridium (Ir), ruthenium (Ru), tantalum (Ta), platinum (Pt), palladium (Pd), bismuth (Bi), titanium (Ti), and tungsten (W), or an alloy thereof.

8. The memory device of claim 1, wherein the free layer includes cobalt (Co).

9. The memory device of claim 1, wherein the free layer has a synthetic anti-ferromagnetic (SAF) structure.

10. The memory device of claim 9, wherein the SAF structure includes a first ferromagnetic layer, a non-magnetic layer, and a second ferromagnetic layer, which are sequentially stacked.

11. The memory device of claim 10, wherein the first ferromagnetic layer includes a Co, Ni, and Co multilayer structure,
the non-magnetic layer includes at least one of platinum (Pt), tungsten (W), tantalum (Ta), ruthenium (Ru), chromium (Cr), rhodium (Rh), palladium (Pd), molybdenum (Mo), niobdenum (Nb), or nickel (Ni), and
the second ferromagnetic layer includes a CoFeB single layer.

12. The memory device of claim 1, further comprising:
an electrode on the fixed layer.

13. The memory device of claim 12, wherein the electrode includes at least one of titanium nitride (TiN) or gold (Au).

14. A memory device comprising:
a heavy metal layer;
a free layer on the heavy metal layer;
a first dielectric layer on the free layer, the first dielectric layer including a plurality of first regions and a plurality of second regions with respective ones of the plurality of first regions therebetween;
a plurality of fixed layers on the plurality of first regions of the first dielectric layer; and
a second dielectric layer on the plurality of second regions of the first dielectric layer, the second dielectric layer including MgO, AlOx, SiOx, HfOx, or a combination thereof.

15. The memory device of claim 14, wherein the first dielectric layer includes MgO.

16. The memory device of claim 14, further comprising:
a third dielectric layer on the second dielectric layer.

17. The memory device of claim 16, wherein the third dielectric layer includes at least one of SiO₂ or AlOx.

18. The memory device of claim 14, further comprising:
an electrode on at least one of the plurality of fixed layers.

19. The memory device of claim 14, further comprising:
a plurality of electrodes, each of the plurality of electrodes on a respective fixed layer of the plurality fixed layers.

20. The memory device of claim 14, wherein the free layer has a synthetic antiferromagnetic (SAF) structure.
